(19) United States
(12) Patent Application Publication
(10) Pub. No.: US 2023/0384180 A1
(43) Pub. Date: Nov. 30, 2023

(54) REINFORCEMENT AND BEARING CAPACITY CALCULATION METHOD FOR SELF-STRESSED BRIDGE DECK LINK SLAB

(71) Applicants: SHANDONG HI-SPEED GROUP CO., LTD., Jinan (CN); SHANDONG UNIVERSITY, Jinan (CN)

(72) Inventors: Qifeng WANG, Jinan (CN); Zhi GE, Jinan (CN); Chuan WANG, Jinan (CN); Yifeng LING, Jinan (CN); Ning ZHANG, Jinan (CN); Hongzhi ZHANG, Jinan (CN); Xiang GAO, Jinan (CN); Yuliang WANG, Jinan (CN); Hongyuan XIAO, Jinan (CN); Yanhua GUAN, Jinan (CN); Renjuan SUN, Jinan (CN); Meijun LIANG, Jinan (CN); Yujie FENG, Jinan (CN)

(21) Appl. No.: 18/321,811

(22) Filed: May 23, 2023

(30) Foreign Application Priority Data
May 24, 2022 (CN) 202210574064.7

(51) Int. Cl. G01M 5/00; E01D 19/12

(52) U.S. Cl. CPC G01M 5/0041; E01D 19/125; E01D 2101/26

(57) ABSTRACT

A reinforcement and bearing capacity calculation method for a self-stressed bridge deck link slab includes: calculating a cross-section moment of inertia of the link slab and a negative moment borne by the link slab; introducing a design self-stress according to stress distribution of the self-stressed bridge deck link slab, whether reinforced or un-reinforced; calculating a cracking moment of the plain self-stressed bridge deck link slab, comparing the cracking moment and the negative moment, proceeding to the next step, or configuring a structural reinforcement as needed; determining a design strength of reinforcement, selecting a reinforcement ratio, and calculating a resisting moment of the link slab; comparing the resisting moment and the negative moment of the link slab, design conditions are satisfied, or configuring the reinforcement ratio and carrying out iterative calculation to obtain a resisting moment; and analyzing stress on the reinforcement and concrete.

### CROSS-REFERENCE TO RELATED APPLICATIONS

This application claims priority to Chinese Patent Application Ser. No. CN202210574064.7 filed on 24 May 2023.

### FIELD OF THE INVENTION

The present disclosure relates to a reinforcement and bearing capacity calculation method for a self-stressed bridge deck link slab, belonging to the technical field of bridge engineering.

### BACKGROUND OF THE INVENTION

In jointless construction of a simply supported beam bridge, concrete or other building materials are continuously cast to form the bridge decks, and bridge deck link slabs are used in place of expansion joints to provide resistance to negative moment cracking and deformation.

Self-stressed bridge deck link slabs are bridge components formed by casting of expansive concrete. The principle of self-stressing is that the expansive concrete expands and deforms in the hardening process, the deformation generates a tensile stress on reinforcement which constrains the deformation and generates an opposite compressive stress on the expansive concrete according to the balance, i.e., the self-stress.

The application of the self-stressed bridge deck link slabs in the jointless bridge deck structure needs a set of theoretical design and calculation methods. However, there is no relevant literature on the application of the self-stressed bridge deck link slabs in the jointless bridge deck structure, and also no corresponding reinforcement design and bearing capacity calculation method. It is of great theoretical significance and application value to propose a corresponding reinforcement design and bearing capacity calculation method based on the characteristics of pre-stressed link slabs.

### SUMMARY OF THE INVENTION

The technical problem to be solved by the present disclosure is to provide a reinforcement design and bearing capacity calculation method for a self-stressed bridge deck link slab according to the characteristics of stress distribution of the self-stressed link slab in a restricted state on the basis of existing theoretical design and calculation methods for bridge deck link slabs, so as to provide a design reference and a theoretical supplement for the application of the self-stressed bridge deck link slab in a continuous bridge structure.

It should be noted that the two ends of the self-stressed bridge deck link slab of the present disclosure are subjected to semi-rigid constraints under the action of an ordinary concrete bridge deck pavement. As shown in FIGS. 1-3, the self-stressed bridge deck link slab is formed by pouring expansive concrete. Due to the nature of the material and the constraint force on the two ends of the self-stressed bridge deck link slab, the expansive concrete is also referred to as self-stressed concrete, and plain expansive concrete and plain self-stressed bridge deck link slabs refer to un-reinforced expansive concrete and un-reinforced self-stressed bridge deck link slabs, respectively.

The technical solution of the present disclosure is as follows:

A reinforcement and bearing capacity calculation method for a self-stressed bridge deck link slab, includes the following steps:
(1) calculating a cross-section moment of inertia of the self-stressed bridge deck link slab and a negative moment Mₐ borne by the link slab;
(2) introducing a design self-stress according to stress distribution of the self-stressed bridge deck link slab, whether reinforced or un-reinforced, in a continuous bridge structure;
(3) introducing a self-stress in a case that the self-stressed bridge deck link slab is un-reinforced, calculating a cracking moment M_{cr} of the plain self-stressed bridge deck link slab, comparing the cracking moment M_{cr} and the negative moment Mₐ, and if Mₐ≥M_{cr}, proceeding to step (4), otherwise, configuring structural reinforcement as needed, and proceeding directly to step (6), wherein the configuration of the structural reinforcement may be performed with reference to the prior art, for example, arranging a reinforcing mesh similar to that used for paving a reinforced bridge deck in the bottom of the link slab along the width direction of the link slab;
(4) determining a design strength of reinforcement, selecting a reinforcement ratio, and calculating a resisting moment Mᵤ of the self-stressed bridge deck link slab;
(5) comparing the resisting moment Mᵤ and the negative moment Mₐ of the link slab, and if Mᵤ≥Mₐ, indicating that design conditions are satisfied, otherwise, configuring the reinforcement ratio and carrying out iterative calculation to obtain a resisting moment Mᵤ satisfying the conditions; and
(6) analyzing stress on the reinforcement and concrete to complete design.

Preferably, in step (1), firstly, a length Lₗₛ of the self-stressed bridge deck link slab and a length L_{dz} of a debonding strip are determined according to spans of a simply supported beam bridge, the length of the link slab being 0.075 times of the sum of two adjacent spans, and the length of the debonding strip being 0.05 times of the sum of two adjacent spans;
a rotation angle at beam ends is determined according to 1/600 of a maximum span of the simply supported beam bridge, i.e., the rotation angle at beam ends is

$${θ}_{max} = \frac{3}{L} \cdot \frac{L}{600} ,$$

the cross-section moment of inertia of the link slab is determined according to a width b and a height h of the link slab, i.e.,

$${I}_{ls} = \frac{{bh}^{3}}{12} ,$$

and the negative moment borne by the link slab is determined from the cross-section moment of inertia and the rotation angle at beam ends, i.e.,

$${M}_{a} = \frac{2 {E}_{c} {I}_{ls}}{{L}_{dz}} {θ}_{max} ,$$

where L is a calculated span of the simply supported beam bridge, and E_{c} is an elastic modulus of self-stressed concrete.

Preferably, in step (2), the introduction of the self-stress takes into account the following assumptions:
(1) the variation of temperature has little effect on the elastic modulus of the self-stressed concrete, and the elastic modulus increases logarithmically with time;
(2) the two ends of the self-stressed concrete link slab are subjected to semi-rigid constraints under the action of an ordinary concrete bridge deck pavement;
(3) the reduced expansive deformation of the link slab under the constraints of ordinary concrete is equal to a free expansive deformation of the link slab minus an elastic shrinkage deformation and a creep deformation of the link slab under stress;
(4) at a moment i, an initial contact state between the self-stressed concrete link slab and the ordinary concrete bridge deck pavement is obtained, i.e., the compressive strength of the self-stressed concrete reaches a certain value, and the expansive deformation of the self-stressed concrete begins to produce the self-stress;
(5) at a moment j, the free expansive deformation of the self-stressed concrete is approximately stable, and the expansive deformation no longer increases; and
(6) the self-stress of the link slab in the un-reinforced state is uniformly distributed in the cross section of the link slab, and in the reinforced state, in view of safety, only the self-stress distributed near the reinforcement region of the link slab is considered, while in the present disclosure, the self-stress is considered only in the upper half region of the cross section of the link slab in the reinforced state.

The self-stress is introduced using the following calculation formula:

$$\{ \begin{matrix}{f}_{sx}^{′} = {E}_{c , {t}_{( j - i ) / 2}} {ε}_{c , s} + Δ {f}_{st}^{′} in the reinforced state of the link slab \\ {f}_{sx} = {f}_{s ρ} + Δ {f}_{st} in the un - reinforced state of the link slab\end{matrix}$$

where fₛₓ′ is a design self-stress of the link slab in an un-reinforced state, E_{c, t}_{_{(j−i)/2}} is an elastic modulus of the expansive concrete at a moment (j−i)/2, ε_{c,s} is an expansive deformation of the expansive concrete under constraints of the continuous structure, and equals to a free expansive deformation of the expansive concrete minus an elastic shrinkage deformation and a creep deformation of the expansive concrete, which is represented as ε_{c,s}=ε_{c,0}−ε_{c,el}−ε_{c,cr}, where ε_{c,0} is the free expansive deformation of the expansive concrete, ε_{c,el} is the elastic shrinkage deformation of the expansive concrete, and ε_{c,cr} is the creep deformation of the expansive concrete, wherein the free expansive deformation is determined with reference to the test method required in the standard Expansive Agents for Concrete (GB/T 23439-2017), and the elastic shrinkage deformation is measured using a non-contact concrete shrinkage deformation instrument, wherein a cast iron detachable iron mould with a size of 100×100×515 mm may be used, and the pouring sequence is as follows: firstly, ordinary concrete is poured at the two ends of the mould, after the concrete has set and hardened for 28 days, a U-shaped iron target is buried in the instrument, and at the same time, a self-stressed concrete material is poured at the middle part of the mould, the self-stressed concrete material is poured until j, then the expansive deformation of the self-stressed concrete tends to be stable, the limits at the two ends of the iron mould are removed, and a strain value generated by a strain gauge is recorded as the elastic shrinkage of the expansive concrete; the creep deformation is determined according to calculation formulas in the specification CEB-FIP;

Δfₛₜ′ is a variation of stress caused by a variation of temperature of the plain expansive concrete link slab, Δfₛₜ′ =E_{c,t}(T−Tₛⱼ)α_{c}, where E_{c,t} is an elastic modulus of the expansive concrete at a moment t,

$${E}_{c , t} = \sqrt{\frac{t}{{c}_{1} + {c}_{2} t}} {E}_{c , 28} ,$$

T is a temperature of a region where the self-stressed bridge deck link slab is casted, Tₛⱼ is a temperature under laboratory conditions, taken as 20° C., t is the age, c₁ and c₁ are constants which may be determined by experimental law fitting, and specifically, may be determined with reference to the static compression elastic modulus test method in the Standard for Test Method of Mechanical Properties on Ordinary Concrete (GB T50081-2002), and obtained by fitting a law of variation of the self-stressed concrete with the age of the elastic modulus, which is a conventional experiment and will not be described in detail herein;

E_{c,28} is an elastic modulus of the expansive concrete at the age of 28 days, and α_{c} is a linear expansion coefficient of the self-stressed concrete;

fₛₓ is a design self-stress of the link slab in a reinforced state, fₛₚ is a variation of stress caused by a variation of reinforcement ratio of the link slab, fₛₚ=ρₓEₛεₛₓ, where ρₓ is the reinforcement ratio of the link slab, Eₛ is an elastic modulus of the reinforcement, and εₛₓ is a constrained expansive deformation produced by the link slab with different reinforcement ratios, and the constrained expansive deformation varies with the reinforcement ratio in different reinforcement ratio ranges in the following law:

$$\{ \begin{matrix}{ε}_{sx} = A - 100 B {ρ}_{x} + 100 lnC {ρ}_{x}^{2} 0.5 \% \leq ρ \leq 1.5 \% \\ {ε}_{sx} = {De}^{- {αρ}_{x}} 1.5 \% < ρ\end{matrix}$$

the values of A, B, C and D in the formula may be obtained by experimental law fitting, specifically, by measuring the constrained expansive deformation according to the standard Expansive Agents for Concrete (GB/T 23439-2017), wherein the strain is measured by changing the diameter of the reinforcing bars, i.e., changing the reinforcement ratio of the self-stressed concrete, and as the reinforcement ratio increased, the constrained deformation varies in a binary linear law or exponential law with 1.5% as a boundary, and the values of A, B, C and D in the above formula are obtained by curve fitting of the variation law of the constrained expansive deformation with the reinforcement ratio;

Δfₛₜ is a variation of stress caused by a variation of temperature of the expansive concrete link slab in the reinforced state,

$$Δ {f}_{st} = \frac{{ρ}_{x} {E}_{s} ( T - {T}_{sj} )}{1 + {α}_{E} {ρ}_{x}} ( {α}_{c} - {α}_{s} ) ,$$

where αₛ is a linear expansion coefficient of the reinforcement, and α_{E} is a ratio of the elastic modulus of the reinforcement to the elastic modulus of concrete.

Preferably, in step (3), the calculating a cracking moment M_{cr} of the plain self-stressed bridge deck link slab includes:
1) when calculating the cracking moment, introducing the self-stress fₛₓ′ according to the restriction around a uniform compressive pre-stress produced by surrounding constraints of the link slab on a cross section of the link slab, and calculating a horizontal pressure on the cross section of the concrete in an initial state: Fsx=fₛₓ′bh;
2) calculating a decompression moment: M₀=fₛₓ′·Wₒ=⅙fₛₓ′bh²;
3) according to a horizontal force balance equation of concrete stress states:

$$\frac{{bx}^{2}}{h - x} {f}_{td} = \frac{3}{4} b ( h - x ) {f}_{td} ,$$

calculating the cracking moment of a concrete link slab: M_{cr,c}=0.256f_{td}bh²; and
4) calculating the cracking moment of the self-stressed concrete link slab: M_{cr}=0.256f_{td}bh²+⅙fₛₓ′bh²;
where f_{td} is a design axial tensile strength of concrete; Wₒ is an inertia resisting moment of concrete; x is a distance between a bottom surface and a neutral axis of the link slab.

Preferably, in step (4), the determining a design strength of reinforcement includes:
a) according to a stress-strain relationship of self-stressed concrete and reinforcement, defining the following physical equation:

f_{td}=E_{c}εₜ₀=0.5E_{c}εₜᵤ

f_{y}=Eₛεₛ−fₛₛ
where f_{td} is a design axial tensile strength of concrete; E_{c} is an elastic modulus of self-stressed concrete; εₜ₀ is a tensile strain at yield of self-stressed concrete; εₜᵤ is an ultimate tensile strain of self-stressed concrete; Eₛ is the elastic modulus of the reinforcement; εₛ is a strain of the reinforcement under load; f_{y} is a stress produced when the strain of the reinforcement is εₛ; fₛₛ is a stress loss caused by stress relaxation of the reinforcement under self-stress, and if fₛₛ/fₚₖ≤0.5, fₚₖ being an ultimate tensile strength of reinforcement, fₛₛ is 0, and if fₛₛ/fₚₖ>0.5, fₛₛ is determined with reference to the specification Technical Specifications for Construction of Highway Bridges and Culverts; and
b) assuming that the reinforcement and the concrete are deformed in a coordinated manner, setting an upper limit strength of reinforcement as 40% of the yield strength, namely f_{y}≤0.4f_{sd}, calculating the strain of the reinforcement, and when the strain reaches the ultimate tensile strain of concrete εₜᵤ, determining whether or not σₛ=Eₛεₜᵤ is greater than or equal to 0.4f_{sd}, and if not, namely σₛ=Eₛεₜᵤ is less than 0.4f_{sd}, then taking the design strength of reinforcement as μ times of the yield strength

$$μ = \frac{{E}_{S} {ε}_{tu}}{{f}_{sd}} ;$$

if so, namely σₛ=Eₛεₜᵤ is greater than or equal to 0.4fₛ, taking the design strength of reinforcement as 40% of the yield strength;
in the formula, 40% is an empirical value proposed on the basis that in bending tests of the link slab, under the test conditions, the reinforcement of the link slab endures up to 40% of its yield strength, then the concrete cracks and quits the work.

Preferably, in step (4):
\textcircled{1} when the design strength of reinforcement is μ times of the yield strength, taking the reinforcement ratio as ρ, and establishing an horizontal force balance equation of the cross section of the link slab according to the stress distribution of the cross section of the link slab as follows:

$$\frac{1}{2} bx \cdot \frac{x}{h - x} \cdot 2 {f}_{td} = \frac{3}{4} b ( h - x ) {f}_{td} + {f}_{sx} b ( h - x ) + μ ( ρ {f}_{sd} bh - {f}_{ss} )$$

where

$$\frac{1}{2} bx \cdot \frac{x}{h - x} \cdot 2 {f}_{td}$$

is a compressive stress of the self-stressed concrete, ¾b(h−βx)f_{td} is a tensile stress of the self-stressed concrete, fₛₓb(h−x) is a self-stress of the self-stressed concrete, and μ(ρf_{sd}bh−fₛₛ) is a tensile stress of the reinforcement, wherein when calculating the self-stress of the self-stressed concrete, the fₛₓ related to the self-stressed concrete is introduced, and when calculating the tensile stress of the reinforcement, the stress loss fₛₛ caused by constraints of the reinforcement on the expansion of the self-stressed concrete is considered; and
calculating x according to a force balance equation, summing moments produced by four forces with respect to the neutral axis, and calculating a resisting moment of the bearing capacity of the link slab:

$${M}_{u} = \frac{1}{2} μ ( ρ {f}_{sd} bh - {f}_{ss} ) ( h - x ) + {f}_{sx} b \frac{{( h - x )}^{2}}{2} + \frac{11}{24} {b ( h - x )}^{2} {f}_{td} + \frac{2}{3} ( \frac{{bx}^{3}}{h - x} ) {f}_{td} ;$$

\textcircled{2} when the design strength of reinforcement is 40% of the yield strength, namely the concrete is in an elastic or elastic-plastic stage, establishing a horizontal force balance equation in such condition:

$$\frac{1}{2} bx \cdot \frac{x}{h - x} \cdot 2 {f}_{td} = \frac{3}{4} b ( h - x ) {f}_{td} + {f}_{sx} b ( h - x ) + 0.4 ( ρ {f}_{sd} bh - {f}_{ss} )$$

summing moments produced by four forces with respect to the neutral axis, and calculating a resisting moment of the bearing capacity of the link slab:

$${M}_{u} = \frac{1}{2} \cdot 0.4 \cdot ( ρ {f}_{sd} bh - {f}_{ss} ) ( h - x ) + {f}_{sx} b \frac{{( h - x )}^{2}}{2} + \frac{11}{24} {b ( h - x )}^{2} {f}_{td} + \frac{2}{3} ( \frac{{bx}^{3}}{h - x} ) {f}_{td} .$$

Preferably, the step (6) specifically includes:
calculating respective tensile and compressive stresses of the reinforcement and the concrete under an actual stress conditions according to stress-strain distribution of the link slab with a design reinforcement, analyzing whether or not the stresses of the reinforcement and the concrete under load exceed stresses bearable by the reinforcement and the concrete, and determining whether or not the link slab cracks;
wherein
the stress bearable by the reinforcement is the yield strength of the reinforcement f_{sd}, the tensile stress bearable by the concrete is the design axial tensile strength of the self-stressed concrete f_{td}, and the compressive stress bearable by the concrete is the design axial compressive strength of the self-stressed concrete f_{cd} (namely, the experimentally measured compressive strength of 28 days);
the tensile stress of the self-stressed concrete (at the upper section of link slab) is: σ_{cl}=

$$\frac{{M}_{a} ( h - x )}{{I}_{conversion}} - {f}_{sx} ;$$

the compressive stress of the self-stressed concrete (at the lower section of link slab) is:

$${σ}_{cy} = \frac{{M}_{a} x}{{I}_{conversion}} ;$$

the tensile stress of the reinforcement is:

$${σ}_{sl} = 2 {α}_{E} \frac{{M}_{a} ( h - x )}{{I}_{conversion}} + {f}_{ss} ;$$

in the formulas, the tensile stress of the self-stressed concrete is a tensile stress of the concrete caused by external load minus a compressive pre-stress of the self-stressed concrete caused by constraints of the reinforcement; the tensile stress of the reinforcement is a tensile stress of concrete caused by external load plus a stress loss caused by constraints of the reinforcement on the expansion of the self-stressed concrete;

$${I}_{conversion} = \frac{( 1 - ρ ) {bh}^{3}}{12} + 2 {α}_{E} ρ {bh ( h - x )}^{2} , {α}_{E} = \frac{{E}_{S}}{{E}_{c}} .$$

Insofar as the present disclosure is not exhaustive, the prior art can be used.

The present disclosure has the following beneficial effects.
1) According to the present disclosure, aiming at the limit conditions of the self-stressed link slab structure, the stress condition of the self-stress link slab under the constraint of the bridge deck pavement is reasonably analyzed, and the theoretical formula for calculating the self-stress of the self-stressed concrete link slab in the reinforced state and the un-reinforced state is provided, which provides a theoretical design reference for the application of the self-stressed link slab in the continuous bridge deck structure.
2) In the un-reinforced state, the self-stress of the plain self-stressed concrete link slab is uniformly distributed on the cross section of the link slab under the constraint of the surrounding bridge deck pavement, and this force characteristic increases the cracking load of the link slab. The present disclosure provides a theoretical formula for calculating the self-stress of the self-stressed concrete link slab in the un-reinforced state and provides a calculation method for the cracking moment of the plain self-stressed concrete link slab. Besides, in the calculation process, increases a procedure for calculating the negative moment borne by the link slab and comparing it with the cracking moment value of the self-stressed concrete link slab, and when the cracking load is large enough, the reinforcement design of the link slab can be completed without reinforcement.
3) In the calculation formula of introducing the self-stress in the reinforced state, the influence of the reinforcement ratio on the self-stress is considered, the constrained expansive deformation of the link slab varies with the reinforcement ratio, and the self-stress of the self-stressed concrete link slab produced with different types of reinforcement and various reinforcement ratios can be calculated by fitting corresponding parameters, thus solving the problem that the self-stress of the self-stressed concrete changes under the influence of the type of reinforcement and the reinforcement ratio.
4) In the present disclosure, different parameters are introduced into the calculation formula of the self-stress, and corresponding formulas are derived to calculate the self-stress of the link slab subjected to the temperature in the link slab with or without the reinforcement, thus solving the problem that the self-stress of the self-stressed concrete changes under the influence of the temperature, and allowing the calculation formula to be applied in various temperature environments.
5) Based on the tensile stress-strain relationship of the self-stressed concrete, the present disclosure provides a method of firstly theoretically calculating whether the self-stressed concrete reaches the ultimate tensile strain and whether the reinforcement reaches the upper limit strength, i.e., 40% of the yield strength, and dividing the design strength of the reinforcement into two conditions, i.e., the strength when the strain reaches the ultimate tensile strain of the concrete and 40% of the yield strength of the reinforcement, respectively, to calculate the reinforcement ratio, so as to make the structural calculation safer.
6) In the present disclosure, when calculating the resisting moment of the link slab in the reinforced state, the design self-stress is brought in according to the force characteristics of the cross section of the link slab, and the resisting moment of the link slab under different reinforcement ratios and different self-stresses can be calculated by formulas.

### BRIEF DESCRIPTION OF THE DRAWINGS

FIG. 1 is a schematic diagram of a simply supported beam bridge deck link slab;

FIG. 2 is a schematic diagram showing the stress condition of the self-stressed bridge deck link slab in an un-reinforced state;

FIG. 3 is a schematic diagram showing the stress condition of a self-stressed bridge deck link slab in a reinforced state;

FIG. 4 is a flow chart of a reinforcement and bearing capacity calculation method for a self-stressed bridge deck link slab;

FIG. 5 is a schematic diagram showing the stress-strain constitutive relationship of self-

stressed concrete and reinforcement in tension, in which (a) is concrete and (b) is reinforcement;

FIG. 6 is a schematic diagram showing the stress-strain variation relationship of the stress cracking of the cross section of the self-stressed concrete link slab, in which (a) is the distribution of the cross section, (b) is the distribution of strain, (c) is the distribution of prestress, (d) is a decompression stress, (e) is the distribution of stress when the crack is imminent, and (f) is a calculated stress diagram;

FIG. 7 is a schematic diagram showing the stress-strain variation relationship of the stress cracking of the cross section of the conventional tensioned reinforced pre-stressed concrete link slab, in which (a) is the distribution of the cross section, (b) is the distribution of strain, (c) is the distribution of prestress, (d) is the stress acting on the load, (e) is the stress under load, (f) is a decompression stress, and (g) is a calculated stress diagram; and

FIG. 8 is a schematic diagram showing the stress-strain variation relationship of the stress cracking of the cross section of the self-stressed reinforced concrete link slab, in which (a) is the distribution of the cross section, (b) is the distribution of strain, (c) is the distribution of prestress, (d) is the stress under pressure relief, (e) is the distribution of stress when the crack is imminent, and (f) is a calculated stress diagram.

### DETAILED DESCRIPTION OF THE EMBODIMENTS

In order that the technical problems, technical solutions and advantages to be solved by the present disclosure will become more apparent, a detailed description will be given below with reference to the accompanying drawings and specific embodiments, but is not limited thereto. What is not described in detail in the present invention may be refereed as conventional techniques in the art.

### Embodiment 1

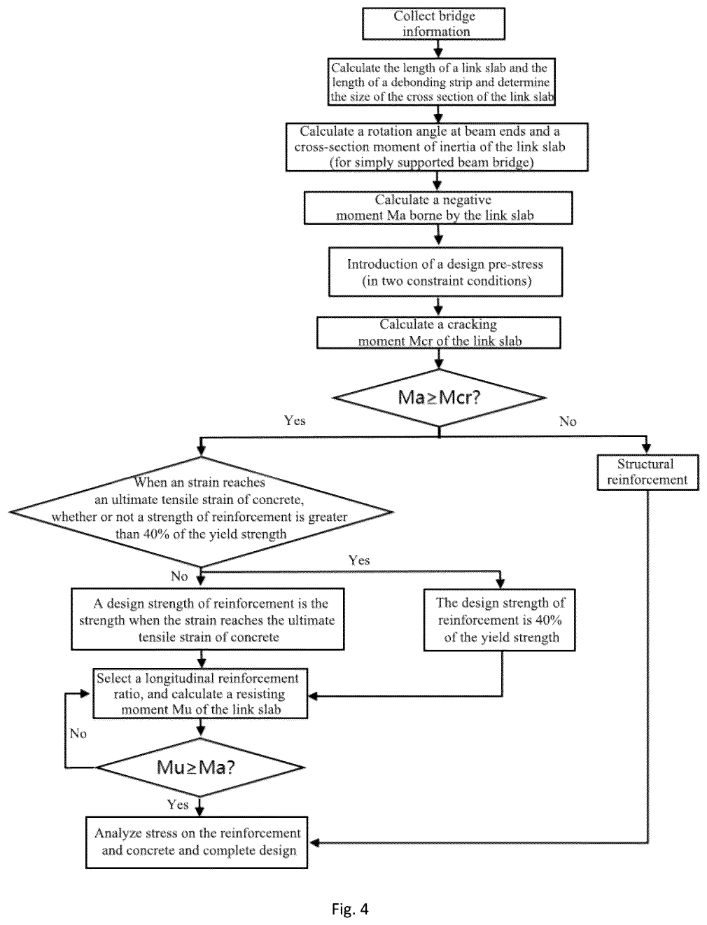

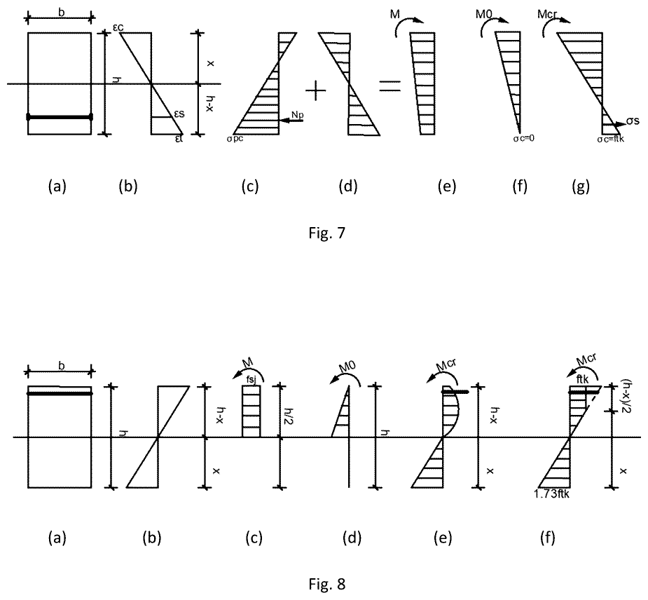

A reinforcement and bearing capacity calculation method for a self-stressed bridge deck link slab, as shown in FIGS. 1 to 8, includes the following steps:
(1) A cross-section moment of inertia of the link slab and a negative moment Mₐ borne by the link slab are calculated.

Firstly, a length Lₗₛ of the link slab and a length L_{dz} of a debonding strip are determined according to spans of a simply supported beam bridge, the length of the link slab being 0.075 times of the sum of two adjacent spans, and the length of the debonding strip being 0.05 times of the sum of two adjacent spans;
a rotation angle at beam ends is determined according to 1/600 of a maximum span of the simply supported beam bridge, i.e., the rotation angle at beam end is

$${θ}_{max} = \frac{3}{L} \cdot \frac{L}{600} ,$$

the cross-section moment of inertia of the link slab is determined according to a width b and a height h of the link slab, i.e.,

$${I}_{ls} = \frac{{bh}^{3}}{12} ,$$

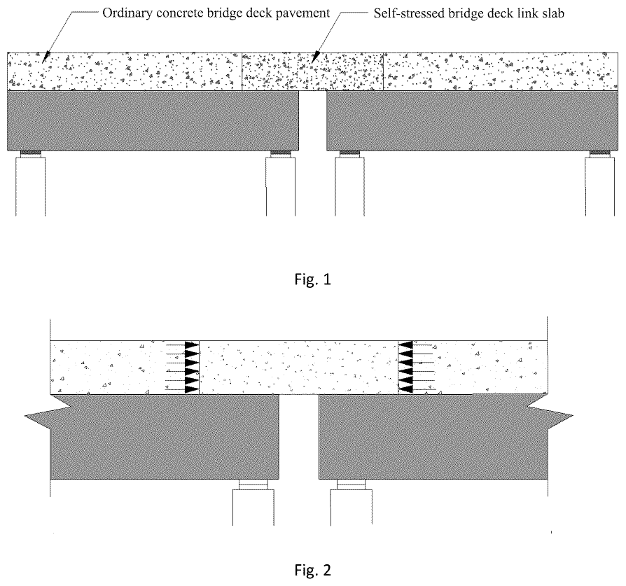

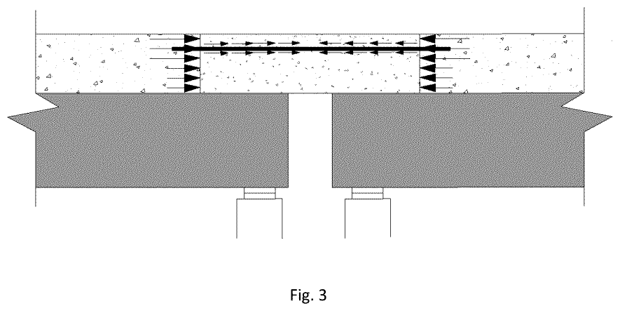

and the negative moment borne by the link slab is determined from the cross-section moment of inertia and the rotation angle at beam ends i.e.,

$${M}_{a} = \frac{2 {E}_{c} {I}_{ls}}{{L}_{dz}} {θ}_{max} ,$$

where L is a calculated span of the simply supported beam bridge, and E_{c} is an elastic modulus of self-stressed concrete.
(2) A design self-stress is introduced according to stress distribution (as shown in FIGS. 2 and 3) of the self-stressed bridge deck link slab, whether reinforced or un-reinforced, in a continuous bridge structure.

The introduction of the self-stress takes into account the following assumptions:
(1) the variation of temperature has little effect on the elastic modulus of the self-stressed concrete, and the elastic modulus increases logarithmically with time;
(2) the two ends of the self-stressed concrete link slab are subjected to semi-rigid constraints under the action of an ordinary concrete bridge deck pavement;
(3) the reduced expansive deformation of the link slab under the constraints of ordinary concrete is equal to a free expansive deformation of the link slab minus an elastic shrinkage deformation and a creep deformation of the link slab under stress;
(4) at a moment i, an initial contact state between the self-stressed concrete link slab and the ordinary concrete bridge deck pavement is obtained, i.e., the compressive strength of the self-stressed concrete reaches a certain value, and the expansive deformation of the self-stressed concrete begins to produce the self-stress;
(5) at a moment j, the free expansive deformation of the self-stressed concrete is approximately stable, and the expansive deformation no longer increases; and
(6) the self-stress of the link slab in the un-reinforced state is uniformly distributed in the cross section of the link slab, and in the reinforced state, in view of safety, only the self-stress distributed near the reinforcement region of the link slab is considered, while in the present disclosure, the self-stress is considered only in the upper half region of the cross section of the link slab in the reinforced state.

The self-stress is introduced using the following calculation formula:

$$\{ \begin{matrix}{f}_{sx}^{′} = {E}_{c , {t}_{( j - i ) / 2}} {ε}_{c , s} + Δ {f}_{st}^{′} in the reinforced state of the link slab \\ {f}_{sx} = {f}_{s ρ} + Δ {f}_{st} in the un - reinforced state of the link slab\end{matrix}$$

where fₛₓ′ is a design self-stress of the link slab in an un-reinforced state, E_{c, t}_{_{(j−i)/2}} is an elastic modulus of the expansive concrete at a moment (j−i)/2, ε_{c,s} is an expansive deformation of the expansive concrete under constraints of the continuous structure, and equals to a free expansive deformation of the expansive concrete minus an elastic shrinkage deformation and a creep deformation of the expansive concrete, which is represented as ε_{c,s}=ε_{c,0}−ε_{c,el}−ε_{c,cr}, where ε_{c,0} is the free expansive deformation of the expansive concrete, ε_{c,el} is the elastic shrinkage deformation of the expansive concrete, and ε_{c,cr} is the creep deformation of the expansive concrete, wherein the free expansive deformation is determined with reference to the test method required in the standard Expansive Agents for Concrete (GB/T 23439-2017), and the elastic shrinkage deformation is measured using a non-contact concrete shrinkage deformation instrument, wherein a cast iron detachable iron mould with a size of 100×100×515 mm may be used, and the pouring sequence is as follows: firstly, ordinary concrete is poured at the two ends of the mould, after the concrete has set and hardened for 28 days, a U-shaped iron target is buried in the instrument, and at the same time, a self-stressed concrete material is poured at the middle part of the mould, the self-stressed concrete material is poured until j, then the expansive deformation of the self-stressed concrete tends to be stable, the limits at the two ends of the iron mould are removed, and a strain value generated by a strain gauge is recorded as the elastic shrinkage of the expansive concrete; the creep deformation is determined according to calculation formulas in the specification CEB-FIP;

Δfₛₜ′ is a variation of stress caused by a variation of temperature of the plain expansive concrete link slab, Δfₛₜ′=E_{c,t}(T−Tₛⱼ)α_{c}, where E_{c,t} is an elastic modulus of the expansive concrete at a moment t,

$${E}_{c , t} = \sqrt{\frac{t}{{c}_{1} + {c}_{2} t}} {E}_{c , 28} ,$$

T is a temperature of a region where the self-stressed bridge deck link slab is casted, Tₛⱼ is a temperature under laboratory conditions, taken as 20° C., t is the age, c₁ and c₁ are constants which may be determined by experimental law fitting, and specifically, may be determined with reference to the static compression elastic modulus test method in the Standard for Test Method of Mechanical Properties on Ordinary Concrete (GB T50081-2002), and obtained by fitting a law of variation of the self-stressed concrete with the age of the elastic modulus, which is a conventional experiment and will not be described in detail herein;

E_{c,28} is an elastic modulus of the expansive concrete at the age of 28 days, and α_{c} is a linear expansion coefficient of the self-stressed concrete;

fₛₓ is a design self-stress of the link slab in a reinforced state, fₛₚ is a variation of stress caused by a variation of reinforcement ratio of the link slab, fₛₚ=ρₓEₛεₛₓ, where ρₓ is the reinforcement ratio of the link slab, Eₛ is an elastic modulus of the reinforcement, and εₛₓ is a constrained expansive deformation produced by the link slab with different reinforcement ratios, and the constrained expansive deformation varies with the reinforcement ratio in different reinforcement ratio ranges in the following law:

$$\{ \begin{matrix}{ε}_{sx} = A - 100 B {ρ}_{x} + 100 lnC {ρ}_{x}^{2} 0.5 \% \leq ρ \leq 1.5 \% \\ {ε}_{sx} = {De}^{- {αρ}_{x}} 1.5 \% < ρ\end{matrix}$$

the values of A, B, C and D in the formula may be obtained by experimental law fitting, specifically, by measuring the constrained expansive deformation according to the standard Expansive Agents for Concrete (GB/T 23439-2017), wherein the strain is measured by changing the diameter of the reinforcing bars, i.e., changing the reinforcement ratio of the self-stressed concrete, and as the reinforcement ratio increased, the constrained deformation varies in a binary linear law or exponential law with 1.5% as a boundary, and the values of A, B, C and D in the above formula are obtained by curve fitting of the variation law of the constrained expansive deformation with the reinforcement ratio;

Δfₛₜ is a variation of stress caused by a variation of temperature of the expansive concrete link slab in the reinforced state,

$$Δ {f}_{st} = \frac{{ρ}_{x} {E}_{s} ( T - {T}_{sj} )}{1 + {α}_{E} {ρ}_{x}} ( {α}_{c} - {α}_{s} ) ,$$

where αₛ is a linear expansion coefficient of the reinforcement, and α_{E} is a ratio of the elastic modulus of the reinforcement to the elastic modulus of concrete.
(3) A self-stress is introduced in a case that the self-stressed bridge deck link slab is un-reinforced, a cracking moment M_{cr} of the plain self-stressed bridge deck link slab is calculated, the cracking moment M_{cr} and the negative moment Mₐ are compared, and if Mₐ≥M_{cr}, proceed to step (4), otherwise, structural reinforcement are configured as needed, and proceed directly to step (6), wherein the configuration of the structural reinforcement may be performed with reference to the prior art, for example, arranging a reinforcing mesh similar to that used for paving a reinforced bridge deck in the bottom of the link slab along the width direction of the link slab.

The calculation of the cracking moment M_{cr} of the plain self-stressed bridge deck link slab includes:
1) when calculating the cracking moment, the self-stress fₛₓ′ is introduced according to a uniform compressive pre-stress caused by surrounding constraints of the link slab on a cross section of the link slab, and a horizontal pressure on the cross section of the concrete in an initial state is calculated: Fsx=fₛₓ′bh;
2) a decompression moment is calculated: M₀=fₛₓ′·Wₒ=⅙fₛₓ′bh²;
3) according to a horizontal force balance equation of concrete stress states:

$$\frac{{bx}^{2}}{h - x} {f}_{td} = \frac{3}{4} b ( h - x ) {f}_{td} ,$$

the cracking moment of a concrete link slab is calculated: M_{cr,c}=0.256f_{td}bh²; and
4) the cracking moment of the self-stressed concrete link slab is calculated: M_{cr}=0.256f_{td}bh²+⅙fₛₓ′bh²;
where f_{td} is a design axial tensile strength of concrete; Wₒ is an inertia resisting moment of concrete; x is a distance between a bottom surface and a neutral axis of the link slab.
(4) A design strength of reinforcement is determined, a reinforcement ratio is selected, and a resisting moment Mᵤ of the self-stressed bridge deck link slab is calculated.

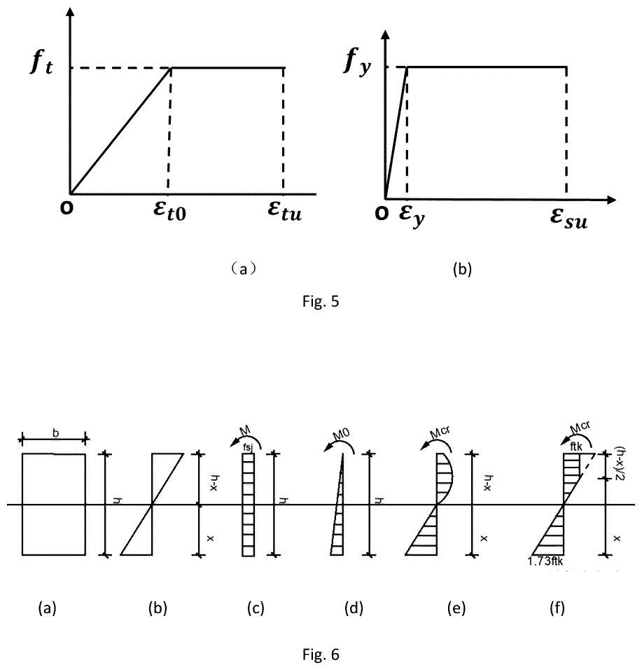

The determination of the design strength of reinforcement includes:
a) according to a stress-strain relationship of self-stressed concrete and reinforcement, the following physical equation is defined, as shown in FIG. 5:

f_{td}=E_{c}εₜ₀=0.5E_{c}εₜᵤ

f_{y}=Eₛε−fₛₛ
where f_{td} is a design axial tensile strength of concrete; E_{c} is an elastic modulus of self-stressed concrete; εₜ₀ is a tensile strain at yield of self-stressed concrete; εₜᵤ is an ultimate tensile strain of self-stressed concrete; Eₛ is the elastic modulus of the reinforcement; εₛ is a strain of the reinforcement under load; f_{y} is a stress produced when the strain of the reinforcement is εₛ; fₛₛ is a stress loss caused by stress relaxation of the reinforcement under self-stress, and if fₛₛ/fₚₖ≤0.5, fₚₖ being an ultimate tensile strength of reinforcement, fₛₛ is 0, and if fₛₛ/fₚₖ>0.5, fₛₛ is determined with reference to the Chinese specification Technical Specifications for Construction of Highway Bridges and Culverts; and
b) assuming that the reinforcement and the concrete are deformed in a coordinated manner, setting an upper limit strength of reinforcement as 40% of the yield strength, namely f_{y}≤0.4f_{sd}, calculating the strain of the reinforcement, and when the strain reaches the ultimate tensile strain of concrete εₜᵤ, determining whether or not σₛ=Eₛεₜᵤ is greater than or equal to 0.4f_{sd}, and if not, namely σₛ=Eₛεₜᵤ is less than 0.4f_{sd}, then taking the design strength of reinforcement as μ times of the yield strength

$$μ = \frac{{E}_{S} {ε}_{tu}}{{f}_{sd}} ;$$

if so, namely σₛ=Eₛεₜᵤ is greater than or equal to 0.4f_{sd}, taking the design strength of reinforcement as 40% of the yield strength;
in the formula, 40% is an empirical value proposed on the basis that in bending tests of the link slab, under the test conditions, the reinforcement of the link slab endures up to 40% of its yield strength, then the concrete cracks and quits the work.
\textcircled{1} When the design strength of reinforcement is μ times of the yield strength, the reinforcement ratio is taken as ρ, see FIGS. 6-8 (in this case, the self-stress is mainly generated by the constraints of the reinforcement, namely, assuming that the self-stress is uniformly distributed only in the tension region of the cross section of the link slab), and an horizontal force balance equation of the cross section of the link slab is established according to the stress distribution of the cross section of the link slab as follows:

$$\frac{1}{2} bx \cdot \frac{x}{h - x} \cdot 2 {f}_{td} = \frac{3}{4} b ( h - x ) {f}_{td} + {f}_{sx} b ( h - x ) + μ ( ρ {f}_{sd} bh - {f}_{ss} )$$

where

$$\frac{1}{2} bx \cdot \frac{x}{h - x} \cdot 2 {f}_{td}$$

is a compressive stress of the self-stressed concrete, ¾b(h−x)f_{td} is a tensile stress of the self-stressed concrete, fₛₓb(h−x) is a self-stress of the self-stressed concrete, and μ(ρf_{sd}bh−fₛₛ) is a tensile stress of the reinforcement, wherein when calculating the self-stress of the self-stressed concrete, the fₛₓ related to the self-stressed concrete is introduced, and when calculating the tensile stress of the reinforcement, the stress loss fₛₛ caused by constraints of the reinforcement on the expansion of the self-stressed concrete is considered; and

x is calculated according to a force balance equation, moments produced by four forces with respect to the neutral axis are summed, and a resisting moment of the bearing capacity of the link slab is calculated:

$${M}_{u} = \frac{1}{2} μ ( ρ {f}_{sd} bh - {f}_{ss} ) ( h - x ) + {f}_{sx} b \frac{{( h - x )}^{2}}{2} + \frac{11}{24} {b ( h - x )}^{2} {f}_{td} + \frac{2}{3} ( \frac{{bx}^{3}}{h - x} ) {f}_{td} ;$$

\textcircled{2} when the design strength of reinforcement is 40% of the yield strength, namely the concrete is in an elastic or elastic-plastic stage, a horizontal force balance equation in such condition is established:

$$\frac{1}{2} bx \cdot \frac{x}{h - x} \cdot 2 {f}_{td} = \frac{3}{4} b ( h - x ) {f}_{td} + {f}_{sx} b ( h - x ) + 0.4 ( ρ {f}_{sd} bh - {f}_{ss} )$$

moments produced by four forces with respect to the neutral axis are summed, and a resisting moment of the bearing capacity of the link slab is calculated:

$${M}_{u} = \frac{1}{2} \cdot 0.4 \cdot ( ρ {f}_{sd} bh - {f}_{ss} ) ( h - x ) + {f}_{sx} b \frac{{( h - x )}^{2}}{2} + \frac{11}{24} {b ( h - x )}^{2} {f}_{td} + \frac{2}{3} ( \frac{{bx}^{3}}{h - x} ) {f}_{td} .$$

(5) The resisting moment Mᵤ and the negative moment Mₐ of the link slab are compared, and if Mᵤ≥Mₐ, it is indicated that design conditions are satisfied, otherwise, the reinforcement ratio is configured and iterative calculation is carried out to obtain a resisting moment Mᵤ satisfying the conditions.
(6) Stress on reinforcement and concrete is analyzed to complete design.

The stress on reinforcement and concrete is analyzed as follows:
respective tensile and compressive stresses of the reinforcement and the concrete under an actual stress conditions are calculated according to stress-strain distribution of the link slab with a design reinforcement, whether or not the stresses of the reinforcement and the concrete under load exceed stresses bearable by the reinforcement and the concrete is analyzed, and whether or not the link slab cracks is determined;
wherein
the stress bearable by the reinforcement is the yield strength of the reinforcement f_{sd}, the tensile stress bearable by the concrete is the design axial tensile strength of the self-stressed concrete f_{td}, and the compressive stress bearable by the concrete is the design axial compressive strength of the self-stressed concrete f_{cd} (namely, the experimentally measured compressive strength of 28 days);
the tensile stress of the self-stressed concrete (at the upper section of link slab) is: σ_{cl}=

$$\frac{{M}_{a} ( h - x )}{{I}_{conversion}} - {f}_{sx} ;$$

the compressive stress of the self-stressed concrete (at the lower section of link slab) is:

$${σ}_{cy} = \frac{{M}_{a} x}{{I}_{conversion}} ;$$

the tensile stress of the reinforcement is:

$${σ}_{sl} = 2 {α}_{E} \frac{{M}_{a} ( h - x )}{{I}_{conversion}} + {f}_{ss} ;$$

in the formulas, the tensile stress of the self-stressed concrete is a tensile stress of the concrete caused by external load minus a compressive pre-stress of the self-stressed concrete caused by constraints of the reinforcement; the tensile stress of the reinforcement is a tensile stress of concrete caused by external load plus a stress loss caused by constraints of the reinforcement on the expansion of the self-stressed concrete;

$${I}_{conversion} = \frac{( 1 - ρ ) {bh}^{3}}{12} + 2 {α}_{E} ρ {bh ( h - x )}^{2} , {α}_{E} = \frac{{E}_{S}}{{E}_{C}} .$$

### Embodiment 2

A reinforcement and bearing capacity calculation method for a self-stressed bridge deck link slab is provided. Two kinds of simply supported beam bridges with spans of 25 m and 20 m are selected for calculation. The length of the link slabs are 3.8 m and 3 m, respectively, with the width both being 1 m and the thickness both 0.12 m. HRB335 is selected as the reinforcement and the yield strength is 280 MPa. The tensile strength of the self-stressed concrete is 2.4 MPa, the elastic modulus of the reinforcement is 2×10₅ MPa, the elastic modulus of the self-stressed concrete 3.25×10⁴ MPa, and the temperature is 20° C., β=1. In order to provide more reinforcement schemes for the self-stress connection device, three self-stresses, i.e., 2, 3 and 4 MPa in the reinforced state and the un-reinforced state, are used in calculation, and three reinforcement ratios are selected for the calculation of the resisting moment for each self-stress, and the above values are taken into the formula required in the calculation process. The calculation results are shown in Table 1:

TABLE 1
Calculation of stress of reinforcement for link slab with self-stress

| | Length | | | | | | | | |
|---|---|---|---|---|---|---|---|---|---|
| | of | | | | | | Concrete stress | | Reinforcement |
| | link | | Design | | | | Tensile | Compressive | tensile |
| Span | slab | Mₐ | self-stress | M_{cr} | Reinforcement | Mᵤ | stress | stress | stress |
| (m) | (m) | (KN · m) | (MPa) | (KN · m) | ratio | (KN · m) | (MPa) | (MPa) | (MPa) |
| 25 | 3.8 | 18.35 | 2 | 13.65 | 1.0% | 18.58 | 2.256725 | 6.255871 | 104.7809 |
| | | | | | 1.5% | 20.50 | 1.65657 | 5.764544 | 90.00788 |
| | | | | | 2.0% | 22.28 | 1.234803 | 5.44729 | 79.62592 |
| | | | 3 | 16.05 | 1.0% | 21.21 | 1.169686 | 6.737394 | 102.6384 |
| | | | | | 1.5% | 23.11 | 0.617039 | 6.214097 | 89.0348 |
| | | | | | 2.0% | 25.04 | 0.219799 | 5.86285 | 79.25659 |
| | | | 4 | 18.45 | 0.5% | 21.87 | 0.826008 | 7.968004 | 118.794 |
| | | | | | 0.6% | 22.22 | 0.653326 | 7.772111 | 114.5434 |
| | | | | | 0.8% | 22.95 | 0.34783 | 7.432246 | 107.0235 |
| 20 | 3.0 | 22.83 | 2 | 13.65 | 2.2% | 23.28 | 1.85591901 | 6.660224 | 94.91493 |
| | | | | | 2.4% | 24.09 | 1.70525331 | 6.560976 | 91.20624 |
| | | | | | 2.6% | 24.92 | 1.56984397 | 6.476621 | 87.87308 |
| | | | 3 | 16.05 | 1.0% | 21.21 | 2.18768004 | 8.38227 | 127.696 |
| | | | | | 1.5% | 23.11 | 1.50010852 | 7.73121 | 110.771 |
| | | | | | 2.0% | 25.04 | 1.00588604 | 7.29421 | 98.60643 |
| | | | 4 | 18.45 | 0.5% | 21.87 | 2.00423796 | 9.91332 | 147.796 |
| | | | | | 0.6% | 22.22 | 1.78939694 | 9.66960 | 142.508 |
| | | | | | 0.8% | 22.95 | 1.40931623 | 9.24676 | 133.152 |

Assuming that the link slab does not have self-stress, the cracking load of the link slab, the reinforcement ratio, and the resisting moment of the link slab as well as the tensile stress bearable by the reinforcement and concrete are calculated, as shown in Table 2:

TABLE 2
Calculation of stress of reinforcement for link slab without self-stress

| | Length | | | | | | | | |
|---|---|---|---|---|---|---|---|---|---|
| | of | | | | | | Concrete stress | | Reinforcement |
| | link | | Design | | | | Tensile | Compressive | tensile |
| Span | slab | Mₐ | self-stress | M_{cr} | Reinforcement | Mᵤ | stress | stress | stress |
| (m) | (m) | (KN · m) | (MPa) | (KN · m) | ratio | (KN · m) | (MPa) | (MPa) | (MPa) |
| 25 | 3.8 | 18.35 | 0 | 8.85 | 1.0% | 12.59 | 4.433797 | 4.944938 | 109.1396 |
| | | | | | 1.5% | 14.59 | 3.712849 | 4.596399 | 91.3932 |
| | | | | | 2.0% | 16.68 | 3.236759 | 4.404616 | 79.67407 |
| 20 | 3.0 | 22.83 | | | 2.2% | 12.59 | 3.84270688 | 5.416828 | 94.58971 |
| | | | | | 2.4% | 14.59 | 3.68041171 | 5.367927 | 90.59475 |
| | | | | | 2.6% | 16.68 | 3.53625891 | 5.328397 | 87.04637 |

It can be seen from Table 1 and Table 2 that, under the same conditions, as compared with the link slab without self-stress, the link slab with self-stress has a larger cracking moment M_{cr} and a larger resisting moment Mᵤ. Besides, the larger the self-stress produced by the self-stressed concrete is, the smaller the required reinforcement ratio is, and also, the data clearly shows that the larger the self-stress value is, the larger the cracking moment is, therefore, the self-stress reinforcement design method is of great significance for practical engineering applications: (1) the reinforcement ratio can be reduced; (2) the cracking load is increased; (3) when the bending moment of the link slab under external load is small, the requirements of non-cracking can be met by the self-stress of the concrete without reinforcement, which provides a numerical reference for this situation.

While the foregoing is directed to the preferred embodiments of the present disclosure, it will be understood by those skilled in the art that numerous modifications and adaptations may be made without departing from the principles of the disclosure, and such modifications and adaptations are intended to be within the scope of the disclosure.

What is claimed is:

1. A reinforcement and bearing capacity calculation method for a self-stressed bridge deck link slab, comprising the following steps:
(i) calculating a cross-section moment of inertia of the self-stressed bridge deck link slab and a negative moment Mₐ borne by the link slab;
(ii) introducing a design self-stress according to stress distribution of the self-stressed bridge deck link slab, whether reinforced or un-reinforced, in a continuous bridge structure;
(ii) introducing a self-stress in a case that the self-stressed bridge deck link slab is un-reinforced, calculating a cracking moment M_{cr} of the plain self-stressed bridge deck link slab, comparing the cracking moment M_{cr} and the negative moment Mₐ, and if Mₐ≥M_{cr}, proceeding to step (iv), otherwise, configuring a structural reinforcement as needed, and proceeding directly to step (vi);
(iv) determining a design strength of reinforcement, selecting a reinforcement ratio, and calculating a resisting moment Mᵤ of the self-stressed bridge deck link slab;
(v) comparing the resisting moment Mᵤ and the negative moment Mₐ, and if Mᵤ≥Mₐ, indicating that design conditions are satisfied, otherwise, configuring the reinforcement ratio and carrying out iterative calculation to obtain a resisting moment Mᵤ satisfying the conditions; and
(vi) analyzing stress on the reinforcement and concrete to complete design.

2. The reinforcement and bearing capacity calculation method for the self-stressed bridge deck link slab according to claim 1, wherein in step (i), firstly, a length Lₗₛ of the self-stressed bridge deck link slab and a length L_{dz} of a debonding strip are determined according to spans of a simply supported beam bridge, the length of the link slab being 0.075 times of the sum of two adjacent spans, and the length of the debonding strip being 0.05 times of the sum of two adjacent spans;
a rotation angle at beam ends is determined according to 1/600 of a maximum span of the simply supported beam bridge, i.e., the rotation angle at beam ends is
$${θ}_{max} = \frac{3}{L} \cdot \frac{L}{600} ,$$
the cross-section moment of inertia of the link slab is determined according to a width b and a height h of the link slab, i.e.,
$${I}_{1 s} = \frac{{bh}^{3}}{12} ,$$
and the negative moment borne by the link slab is determined from the cross-section moment of inertia and the rotation angle at beam ends, i.e.,
$${M}_{a} = \frac{3 {E}_{c} {I}_{ls}}{{L}_{dz}} {θ}_{max} ,$$
where L is a calculated span of the simply supported beam bridge, and E_{c} is an elastic modulus of self-stressed concrete.

3. The reinforcement and bearing capacity calculation method for the self-stressed bridge deck link slab according to claim 1, wherein in step (ii), the self-stress is introduced using the following calculation formula:
$$\{ \begin{matrix}{f}_{sx}^{′} = {E}_{c , {t}_{( j - i ) / 2}} {ε}_{c , s} + Δ {f}_{st}^{′} in the reinforced state of the link slab \\ {f}_{sx} = {f}_{sp} + Δ {f}_{st} in the un - reinforced state of the link slab\end{matrix}$$
where fₛₓ′ is a design self-stress of the link slab in an un-reinforced state, E_{c, t}_{_{(j−i)/2}} is an elastic modulus of the expansive concrete at a moment (j−i)/2, ε_{cs} is an expansive deformation of the expansive concrete under constraints of the continuous structure, and equals to a free expansive deformation of the expansive concrete minus an elastic shrinkage deformation and a creep deformation of the expansive concrete, which is represented as ε_{c,s}=ε_{c,0}−ε_{c,el}−ε_{c,cr}, where ε_{c,0} is the free expansive deformation of the expansive concrete, ε_{c,el} is the elastic shrinkage deformation of the expansive concrete, and ε_{c,cr} is the creep deformation of the expansive concrete; Δfₛₜ′ is a variation of stress caused by a variation of temperature of the plain expansive concrete link slab, Δfₛₜ′ =E_{c,t}(T−Tₛⱼ)α_{c}, where E_{c,t} is an elastic modulus of the expansive concrete at a moment t,
$${E}_{c , t} = \sqrt{\frac{t}{{c}_{1} + {c}_{2} t}} {E}_{c , 28} ,$$
T is a temperature of a region where the self-stressed bridge deck link slab is casted, Tₛⱼ is a temperature under laboratory conditions, taken as 20° C., t is the age, c₁ and c₁ are constants, E_{c,28} is an elastic modulus of the expansive concrete at the age of 28 days, and α_{c} is a linear expansion coefficient of the self-stressed concrete;
fₛₓ is a design self-stress of the link slab in a reinforced state, fₛₚ is a variation of stress caused by a variation of reinforcement ratio of the link slab, fₛₚ=ρₓEₛεₛₓ, where ρₓ is the reinforcement ratio of the link slab, Eₛ is an elastic modulus of the reinforcement, and εₛₓ is a constrained expansive deformation produced by the link slab with different reinforcement ratios, and the constrained expansive deformation varies with the reinforcement ratio in different reinforcement ratio ranges in the following law:
$$\{ \begin{matrix}{ε}_{sx} = A - 100 B {ρ}_{x} + 100 ln C {ρ}_{x}^{2} & 0.5 \% \leq ρ \leq 1.5 \% \\ {ε}_{sx} = {De}^{- α {ρ}_{x}} & 1.5 \% < ρ\end{matrix}$$
the values of A, B, C and D in the formula are obtained by measuring the constrained expansive deformation according to the standard Expansive Agents for Concrete (GB/T 23439-2017), wherein the strain is measured by varying the diameter of the reinforcement, i.e., varying the reinforcement ratio of the self-stressed concrete, and as the reinforcement ratio increased, the constrained deformation varies in a binary linear law or exponential law with 1.5% as a boundary, and the values of A, B, C and D are obtained by curve fitting of the variation law of the constrained expansive deformation with the reinforcement ratio;
Δfₛₜ′ is a variation of stress caused by a variation of temperature of the expansive concrete link slab in the reinforced state,
$$Δ {f}_{st} = \frac{{ρ}_{x} {E}_{s} ( T - {T}_{sj} )}{1 + {α}_{E} {ρ}_{x}} ( {α}_{c} - {α}_{s} ) ,$$
where αₛ is a linear expansion coefficient of the reinforcement, and α_{E} is a ratio of the elastic modulus of the reinforcement to the elastic modulus of concrete.

4. The reinforcement and bearing capacity calculation method for the self-stressed bridge deck link slab according to claim 3, wherein in step (iii), the calculating a cracking moment M_{cr} of the plain self-stressed bridge deck link slab comprises:
a) when calculating the cracking moment, introducing the self-stress fₛₓ′ according to a uniform compressive pre-stress caused by surrounding constraints of the link slab on a cross section of the link slab, and calculating a horizontal pressure on the cross section of the concrete in an initial state: Fsx=ₛₓ′bh;
b) calculating a decompression moment: M₀=fₛₓ′·Wₒ=⅙fₛₓ′bh²;
c) according to a horizontal force balance equation of concrete stress states:
$$\frac{{bx}^{2}}{h - x} {f}_{td} = \frac{3}{4} b ( h - x ) {f}_{td} ,$$
calculating the cracking moment of a concrete link slab: M_{cr,c}=0.256f_{td}bh²; and
d) calculating the cracking moment of the self-stressed concrete link slab: M_{cr}=0.256f_{td}bh²+⅙fₛₓ′bh²;
where f_{td} is a design axial tensile strength of concrete; Wₒ is an inertia resisting moment of concrete; x is a distance between a bottom surface and a neutral axis of the link slab.

5. The reinforcement and bearing capacity calculation method for the self-stressed bridge deck link slab according to claim 4, wherein in step (iv), the process of determining a design strength of reinforcement comprises:
A) according to a stress-strain relationship of self-stressed concrete and reinforcement, defining the following physical equation:
f_{td}=E_{c}εₜ₀=0.5E_{c}εₜᵤ
f_{y}=Eₛεₛ−fₛₛ
where f_{td} is a design axial tensile strength of concrete; E_{c} is an elastic modulus of self-stressed concrete; εₜ₀ is a tensile strain at yield of self-stressed concrete; εₜᵤ is an ultimate tensile strain of self-stressed concrete; Eₛ is the elastic modulus of the reinforcement; εₛ is a strain of the reinforcement under load; f_{y} is a stress produced when the strain of the reinforcement is εₛ; fₛₛ is a stress loss caused by stress relaxation of the reinforcement under self-stress, and if fₛₛ/fₚₖ≤0.5, fₚₖ being an ultimate tensile strength of reinforcement, fₛₛ is 0, and if fₛₛ/fₚₖ>0.5, fₛₛ is determined with reference to the Chinese specification Technical Specifications for Construction of Highway Bridges and Culverts; and
B) setting an upper limit strength of reinforcement as 40% of the yield strength, namely f_{y}≤0.4f_{sd}, calculating the strain of the reinforcement, and when the strain reaches the ultimate tensile strain of concrete εₜᵤ, determining whether or not σₛ=Eₛεₜᵤ is greater than or equal to 0.4f_{sd}, and if not, namely σₛ=Eₛεₜᵤ is less than 0.4f_{sd}, then taking the design strength of reinforcement asμ times of the yield strength
$$μ = \frac{{E}_{s} {ε}_{tu}}{{f}_{sd}} ;$$
if so, namely σₛ=Eₛεₜᵤ is greater than or equal to 0.4f_{sd}, taking the design strength of reinforcement as 40% of the yield strength.

6. The reinforcement and bearing capacity calculation method for the self-stressed bridge deck link slab according to claim 5, wherein the step (iv) comprises:
I) when the design strength of reinforcement is μ times of the yield strength, taking the reinforcement ratio as ρ, and establishing an horizontal force balance equation of the cross section of the link slab as follows:
$$\frac{1}{2} bx \cdot \frac{x}{h - x} \cdot 2 {f}_{td} = \frac{3}{4} b ( h - x ) {f}_{td} + {f}_{sx} b ( h - x ) + μ ( ρ {f}_{sd} bh - {f}_{ss} )$$
where
$$\frac{1}{2} bx \cdot \frac{x}{h - x} \cdot 2 {f}_{td}$$
is a compressive stress of the self-stressed concrete, ¾b(h−x)f_{td} is a tensile stress of the self-stressed concrete, fₛₓb(h−x) is a self-stress of the self-stressed concrete, and μ(ρf_{sd}bh−fₛₛ) is a tensile stress of the reinforcement; and
calculating x according to a force balance equation, summing moments produced by four forces with respect to the neutral axis, and calculating a resisting moment of the bearing capacity of the link slab:
$${M}_{u} = \frac{1}{2} μ ( ρ {f}_{sd} bh - {f}_{ss} ) ( h - x ) + {f}_{sx} b \frac{{( h - x )}^{2}}{2} + \frac{11}{24} {b ( h - x )}^{2} {f}_{td} + \frac{2}{3} ( \frac{{bx}^{3}}{h - x} ) {f}_{td} ;$$
II) when the design strength of reinforcement is 40% of the yield strength, namely the concrete is in an elastic or elastic-plastic stage, establishing a horizontal force balance equation in such condition:
$$\frac{1}{2} bx \cdot \frac{x}{h - x} \cdot 2 {f}_{td} = \frac{3}{4} b ( h - x ) {f}_{td} + {f}_{sx} b ( h - x ) + 0.4 ( ρ {f}_{sd} bh - {f}_{ss} )$$
summing moments produced by four forces with respect to the neutral axis, and calculating a resisting moment of the bearing capacity of the link slab:
$${M}_{u} = \frac{1}{2} \cdot 0.4 \cdot ( ρ {f}_{sd} bh - {f}_{ss} ) ( h - x ) + {f}_{sx} b \frac{{( h - x )}^{2}}{2} + \frac{11}{24} {b ( h - x )}^{2} {f}_{td} + \frac{2}{3} ( \frac{{bx}^{3}}{h - x} ) {f}_{td} .$$

7. The reinforcement and bearing capacity calculation method for the self-stressed bridge deck link slab according to claim 6, wherein the step (vi) specifically comprises:
calculating respective tensile and compressive stresses of the reinforcement and the concrete under an actual stress conditions according to stress-strain distribution of the link slab with a design reinforcement, analyzing whether or not the stresses of the reinforcement and the concrete under load exceed stresses bearable by the reinforcement and the concrete, and determining whether or not the link slab cracks;
wherein
the stress bearable by the reinforcement is the yield strength of the reinforcement f_{sd}, the tensile stress bearable by the concrete is the design axial tensile strength of the self-stressed concrete f_{td}, and the compressive stress bearable by the concrete is the design axial compressive strength of the self-stressed concrete f_{cd};
the tensile stress of the self-stressed concrete is:
$${σ}_{c 1} = \frac{{M}_{a} ( h - x )}{{I}_{conversion}} - {f}_{sx} ;$$
the compressive stress of the self-stressed concrete is:
$${σ}_{cy} = \frac{{M}_{a} x}{{I}_{conversion}} ;$$
the tensile stress of the reinforcement is:
$${σ}_{s 1} = 2 {α}_{E} \frac{{M}_{a} ( h - x )}{{I}_{conversion}} + {f}_{ss} ;$$
in the formulas, the tensile stress of the self-stressed concrete is a tensile stress of the concrete caused by external load minus a compressive pre-stress of the self-stressed concrete caused by constraints of the reinforcement; the tensile stress of the reinforcement is a tensile stress of concrete caused by external load plus a stress loss caused by constraints of the reinforcement on the expansion of the self-stressed concrete;
$${I}_{conversion} = \frac{( 1 - ρ ) {bh}^{3}}{12} + 2 {α}_{E} ρ {bh ( h - x )}^{2} , {α}_{E} = \frac{{E}_{s}}{{E}_{c}} .$$
